(19) United States
(12) Patent Application Publication
(10) Pub. No.: US 2026/0173891 A1
(43) Pub. Date: Jun. 18, 2026

(54) ELECTROSTATIC PROTECTION OF HETEROGENEOUSLY-INTEGRATED SEMICONDUCTORS

(71) Applicant: PseudolithIC, Inc., Santa Barbara, CA (US)

(72) Inventors: Florian Herrault, Agoura Hills, CA (US); Christopher A. Maxey, Arlington, VA (US); James F. Buckwalter, Santa Barbara, CA (US)

(21) Appl. No.: 19/420,221

(22) Filed: Dec. 15, 2025

Related U.S. Application Data
(60) Provisional application No. 63/734,614, filed on Dec. 16, 2024.

(51) Int. Cl. H10W 42/60; H10D 30/47; H10D 80/20; H10W 70/60; H10W 70/65; H10W 70/68; H10W 95/00

(52) U.S. Cl. CPC H10W 42/60; H10D 80/251; H10W 70/614; H10W 70/658; H10W 70/682; H10W 95/00; H10D 30/471

(57) ABSTRACT

A device is described. The device includes an interposer, a high electron mobility transistor (HEMT), and an electrical interface between the HEMT and the interposer. The interposer includes at least one semiconductor material. The HEMT is mounted on the interposer. The interposer includes an integrated electrostatic discharge (ESD) protection circuit that is coupled to the HEMT through the electrical interface.

### CROSS REFERENCE TO OTHER APPLICATIONS

This application claims priority to U.S. Provisional Patent Application No. 63/734,614 entitled ELECTROSTATIC PROTECTION OF HETEROGENEOUSLY-INTEGRATED SEMICONDUCTORS filed Dec. 16, 2024 which is incorporated herein by reference for all purposes.

### BACKGROUND OF THE INVENTION

Electronic assemblies, or hybrid circuits, include microelectronic circuits fabricated separately and assembled together to form a single component. The single component may be encapsulated in an electronic circuit package. Assembling separately fabricated microelectronic circuits allows, for example, testing of all the microelectronic circuits separately prior to assembling them. This testing prior to assembly may improve fabrication yields of the final component. This capability is particularly significant if some of the microelectronic circuits are difficult and/or expensive to manufacture. Assembling separately fabricated microelectronic circuits also allows for combination of microelectronic circuits, which themselves employ different materials and/or different manufacturing processes, into a single final component. This capability can lead to higher circuit performance.

However, electrostatic discharge (ESD) can cause the failure and destruction of electronic devices during test and assembly. For example, build-up of charge on the human body and/or integrated circuit packaging machines may discharge through a contact point such as a wire bond pad. The resulting voltage (e.g., 2000+V in a human body model) can damage or destroy components within the assembly. Consequently, improvements in the testing and assembly of microelectronic circuits are desired.

### BRIEF DESCRIPTION OF THE DRAWINGS

Various embodiments of the invention are disclosed in the following detailed description and the accompanying drawings.

FIGS. 1A-1B depict an embodiment of portions of a device.

FIGS. 2A-2C depict embodiments of devices in which chiplets are coupled with interposers.

FIGS. 3A-3B depict embodiments of devices in which chiplets are coupled with interposers.

FIG. 4 is a flow diagram illustrating an embodiment of process for heterogeneous integration with ESD protection.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Electrostatic discharge (ESD) can cause the failure and destruction of electronic devices during test and assembly. For example, build-up of charge on the human body and/or integrated circuit packaging machines may discharge through a contact point such as a wire bond pad. The resulting voltage (e.g., 2000+V in a human body model) can damage or destroy components within the assembly. External ESD protection (e.g., on a different chip or in an assembly) may be difficult to model and simulate accurately. Further, the external ESD protection may not provide protection during assembly. For example, a sensitive component may be connected to the external ESD protection (e.g., via wire bonding). However, the connection process itself may put the sensitive component at risk of destruction or damage. Consequently, improvements in the testing and assembly of microelectronic circuits are desired.

A device is described. The device includes an interposer, a high electron mobility transistor (HEMT) mounted on the interposer, and an electrical interface between the HEMT and the interposer. The interposer includes at least one semiconductor material and an electrostatic discharge (ESD) protection circuit coupled to the HEMT through the electrical interface.

In some embodiments, the ESD protection circuit is provided in the interposer before the HEMT is mounted on the interposer. The HEMT may be included in a low noise amplifier (LNA). In some such embodiments, the LNA is configured for operation at temperatures as low as 3 Kelvin (e.g., liquid He temperatures or below). The HEMT may be an InP HEMT. In some embodiments, the HEMT is integrated in a chiplet including a front side and a back side. In some such embodiments, the HEMT is mounted on the interposer through physically manipulating the chiplet from the back side. The HEMT may be electrically coupled to the ESD protection circuit through at least one wafer level interconnect. In some embodiments, the ESD protection circuit includes diodes integrated into the interposer. The ESD protection circuit may provide ESD protection for the HEMT against ESD of or by at least one of a human or ESD corresponding to a human body model (HBM). The HBM is a standardized representation of ESD from a human body. The HBM may be used to test the susceptibility of the device to ESD as though the device was touched by a person. In some embodiments, the interposer includes a wafer having a cavity therein. In such embodiments, the HEMT is mounted in the cavity. Moreover, the wafer may include at least one of a passive circuit and an active circuit in addition to the ESD protection circuit.

An electronic assembly is described. The electronic assembly includes an interposer having ESD protection circuits integrated therein and ESD sensitive chiplets. The ESD sensitive chiplets are coupled with the interposer and electrically coupled with the ESD protection circuits through the interposer.

In some embodiments, the ESD protection circuits are provided in the interposer before the ESD sensitive chiplets are mounted on the interposer. The ESD sensitive chiplets may include HEMTs. In some such embodiments, the HEMTs are included in low noise amplifiers (LNAs) that are in the ESD sensitive chiplets. In some embodiments, a chiplet of the ESD sensitive chiplets includes a front side and a back side. In such embodiments, the chiplet may be mounted on the interposer through physically manipulating the chiplet from the back side. The ESD sensitive chiplets being coupled to the interposer includes mounting the ESD sensitive chiplets on the interposer and electrically coupling the HEMT to at least one ESD protection circuit of the ESD protection circuits. The electrical connection may be made through wafer level interconnect(s) for the interposer. In some such embodiments, the ESD protection circuit(s) provide ESD protection for the HEMT against ESD of or by at least one of a human or an HBM. In some embodiments, the interposer includes a wafer having a cavity therein, a chiplet of the plurality of ESD sensitive chiplets is mounted in the cavity. In such embodiments, the wafer may also include a passive circuit and/or an active circuit in addition to the ESD protection circuit.

A method is described. The method includes mounting a HEMT in an interposer. The interposer includes at least one semiconductor material, an ESD protection circuit, and an electrical interface. The method also includes electrically coupling the HEMT to the ESD protection circuit through the electrical interface.

In some embodiments, the ESD protection circuit is provided in the interposer before the HEMT is mounted on the interposer. In some such embodiments, the HEMT is integrated in a chiplet including a front side and a back side. Mounting the HEMT includes physically manipulating the chiplet from the back side. In some embodiments, the HEMT being mounted on the interposer includes electrically coupling the HEMT to the ESD protection circuit through at least one wafer level interconnect in the interposer.

Various features of the device, electronic assembly, and method are described herein. One or more of these features may be combined in manners not explicitly described herein.

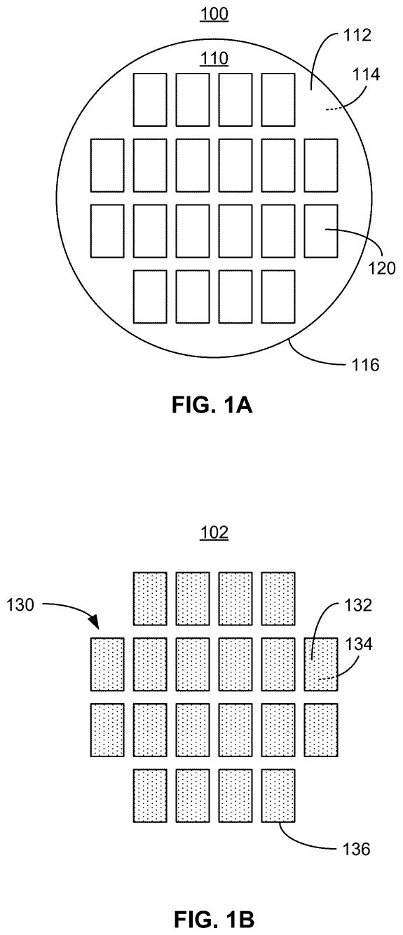

FIGS. 1A-1B depict an embodiment of portions 100 and 102 of a device. FIG. 1A is a diagram 100 illustrating an embodiment of interposer 110. Interposer 110 may provide electrostatic protection for one or more heterogeneously integrated semiconductors. Interposer 110 includes front surface 112 and back surface 114. In diagram 100, front surface 112 is primarily visible. Interposer 110 includes side surface(s) 116, which in various embodiments constitutes a vertical or other sidewall surface or surfaces between back surface 114 and front surface 112. In the embodiment shown, interposer 110 includes cavities 120 (only one of which is labeled). In some embodiments, cavities 120 are through cavities (e.g., holes through interposer 110). Cavities 120 may be shallower than interposer 110 (e.g., depressions in front surface 112). In some embodiments, cavities 120 may be omitted. Interposer 110 includes at least one ESD protection circuit (not shown in diagram 100). In various embodiments, capacitors, inductors, resistors, transistors, diodes, or any other appropriate circuit(s) or electrical component(s) may also be integrated within interposer 110.

Interposer 110 may be or include (e.g., as a mixture of materials or as material layers) silicon, silicon germanium, silicon carbide, silicon on insulator, gallium arsenide, indium phosphide, aluminum nitride, diamond, quartz, alumina, or any other appropriate material(s). In some embodiments, interposer 110 is or includes a dielectric (e.g., quartz, alumina, another ceramic, etc.). Interposer 110 may have layers of one or more of these materials. In various embodiments, interposer 110 is in the form of an oxide material, a crystalline material, a polycrystalline material, an amorphous material, or any other appropriate form. Interposer 110 may include passive and/or active integrated components such as resistors, capacitors, inductors, ESD circuits, diodes, through substrate vias, dielectric layers, signal traces, powered or ground traces, interconnects, wires, metal layers (e.g., signal traces or signal planes), or any other appropriate component(s). In some embodiments, interposer 110 includes multiple areas configured to be diced (e.g., into multiple integrated circuits). Each area may include passive and/or active integrated components.

FIG. 1B is a diagram 102 illustrating an embodiment of chiplets 130 (only one of which is labeled). In some embodiments, chiplets 130 are heterogeneously integrated onto interposer 110 of FIG. 1A. Chiplets 130 have front surfaces 132 (e.g., a frontside surface) and back surfaces 134 (e.g., a backside surface). In diagram 102, front surfaces 132 are primarily visible. Each of chiplets 130 has side surfaces 136, which in various embodiments constitute vertical or sidewall surfaces between front surfaces 132 and back surfaces 134. In some embodiments, chiplets 130 are integrated into cavities 120 of interposer 110. The shape, size, configuration, etc. of cavities 120 may approximate each of chiplets 130.

Chiplets 130 may each be or include (e.g., as a mixture of materials or as material layers) silicon (Si), silicon germanium (SiGe), silicon-on-insulator, gallium arsenide (GaAs), indium phosphide (InP), aluminum nitride, quartz, alumina, gallium nitride (GaN), etc. In various such embodiments, chiplets 130 include layers of one or more of these materials (e.g., in the form of an oxide material, crystalline material, polycrystalline material, amorphous material, etc.). Though shown as uniform, the shape, size, configuration, composition, or any other appropriate property may vary across chiplets 130. For example, each of chiplets 130 may include different electrical component types, may be manufactured separately from each other, etc.

In various embodiments, chiplets 130 include GaN, InP or GaAs or any other material(s) used in forming electrical component(s). Chiplets 130 may be fabricated on a substrate such as Si, SiGe, InP, GaAs, alumina, diamond, etc. Chiplets 130 may include transistors used for RF switches, transmit and/or receive circuits; power switches, amplifiers, etc. Chiplets 130 may include GaAs, InP, GaN, Si CMOS, or other transistors. Chiplets 130 may also be sensitive to electrostatic discharge (ESD) damage. Stated differently, some or all of chiplets 130 include one or more circuits that are sensitive to ESD. For example, each chiplet 130 may include one or more high electron mobility transistors (HEMTs), such as InP HEMTs (not shown in FIG. 1B). The HEMTs may be part of a low noise amplifier (LNA) or other device(s) formed in chiplets 130. Chiplet transistors, as well as other components of chiplets 130, may have smaller and/or more expensive electrical components than those of interposer 110. There may be one, tens, hundreds, thousands or hundreds of thousands of chiplets 130 embedded in or on interposer 110. Interposer 110 may include more passive components, lower cost components, routing (e.g., traces, conductive vias and interconnections), etc. than chiplets 130. Interposer 110 may be fabricated using different microelectronic fabrication techniques or processes than are used to fabricate chiplets 130.

Chiplets 130 and interposer 110 may be made of different materials. For example, interposer 110 may be a silicon wafer while chiplets 130 may be a type III-Nitride material component chiplet or a III-V material chiplet (e.g., an InP chiplet). In some embodiments, chiplets 130 may each be or include an integrated circuit having passive integrated components (e.g., signal traces, interconnects and conductive vias, resistors, inductors and/or capacitors), active components (e.g., a single transistor, multiple transistors, diodes, op-amps, or other components), or any other appropriate component(s).

Chiplets 130 may each include transistor circuitry and/or interconnects to contact pads on front surfaces 132. Chiplets 130 may be high-end pre-fabricated active device chiplets coupled to interposer 110. Chiplets 130 may be integrated onto interposer 110 through pick and place assembly (e.g., on a temporary wafer with an adhesive laminate, on an adhesive laminate, etc.). In some embodiments, chiplets 130 are mounted onto interposer 110 through physically manipulating each chiplet from back surfaces 134. In some embodiments, chiplets 130 are mounted into cavities 120. Further, electrical connection may be made between components of chiplets 130 and circuitry in interposer 110. In some embodiments, an electrical interface between front surfaces 132 of chiplets 130 and front surface 112 of interposer 110 may allow electrical coupling between components of chiplets 130 and circuitry of interposer 110. Electrical coupling between chiplets 130 and interposer 110 may be made via wafer level interconnects. Stated differently, wafer level interconnects may provide an electrical interface between chiplets 130 and circuits in interposer 110. This may improve performance, reliability, and yield for circuitry of chiplets 130.

For example, chiplets 130 may be sensitive to ESD damage. One or more ESD protection circuits integrated within interposer 110 (e.g., before chiplets 130 are mounted on interposer 110) may protect chiplets 130 and circuits therein (e.g., HEMTs) from ESD damage once (e.g., as soon as) chiplets 130 are coupled to interposer 110. The ESD protection circuits may provide ESD protection for chiplets 130 against ESD of or by at least one of a human or a human body model (HBM). The HBM may be used to test the susceptibility of a device including chiplets 130 and/or interposer 110 to ESD. Consequently, processes that may otherwise subject chiplets 130 to ESD damage (e.g., handling by a human) may be performed after chiplet 130 is electrically connected to ESD protection circuits in interposer 110. Thus, reliability and performance may be improved. Further, the yield for fabrication of devices utilizing chiplets 130 may be increased.

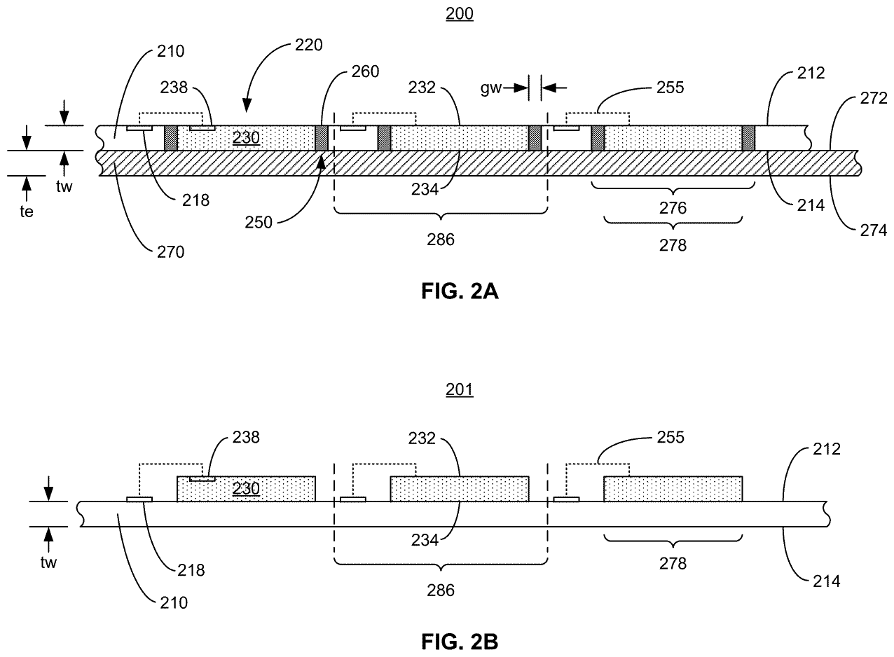

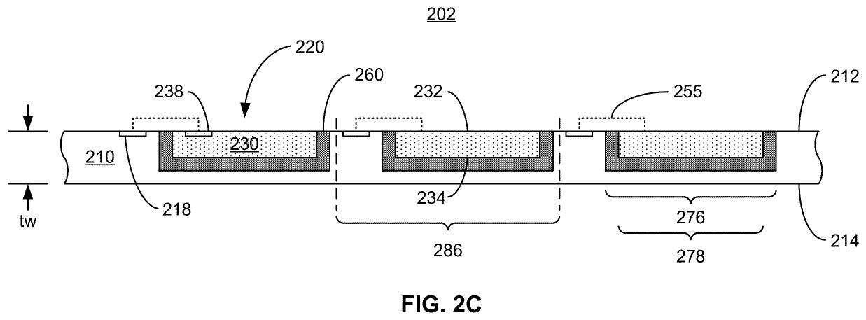

FIGS. 2A-2C depict embodiments of devices 200, 201, and 202 in which chiplets are coupled with interposers. FIG. 2A is a schematic cross-sectional view of device 200 having heterogeneous integration of chiplets 230 (only one of which is labeled) into interposer 210. Interposer 210 includes one or more integrated ESD protection circuits. In some embodiments, interposer 210 and chiplets 230 are analogous to interposer 110 and chiplets 130 of FIGS. 1A-1B.

Device 200 may be an electronic assembly. In the embodiment shown, device 200 includes encapsulation material layer 270 having top surface 272 and back surface 274. Interposer 210 includes back surface 214 and front surface 212, with back surface 214 bonded to top surface 272 of encapsulation material layer 270. Interposer 210 includes cavities 220 (only one of which is labeled) formed over areas 276 (only one of which is labeled) of encapsulation material layer 270. Cavities 220 may be through substrate holes etched in interposer 210 at areas 276. Chiplets 230 may be embedded into the interposer 210 at cavities 220. In some embodiments, cavities 220 extend fully through interposer 210 (i.e., to back surface 214 and to top surface 272 of encapsulation material layer 270). In some embodiments, cavities 220 extend partially through interposer 210 (e.g., analogous to device 202 of FIG. 2C). Cavities 220 may be omitted (e.g., analogous to device 201 of FIG. 2B). Back surface 214 may be directly attached to (e.g., in contact with) top surface 372. The bond between the back surface 214 and the top surface 372 may be a covalent bond, chemical bond, atomic bond, or any other appropriate bond.

Chiplets 230 have back surfaces 234 and front surfaces 232. Back surfaces 234 may be mounted on top surface 272 of encapsulation material layer 270. Back surfaces 234 may be directly attached to (e.g., in contact with) top surface 372. In the embodiment shown, back surface 234 is bonded to portions 278 of areas 276. Portions 278 may be the footprint of chiplets 230 on top surface 272 within cavities 220. Gaps 250 (only one of which is labeled) between chiplets 230 and interposer 210 may be the difference between areas 276 and portions 278. The bond between back surfaces 234 and top surface 272 may be a covalent bond, chemical bond, atomic bond, or any other appropriate bond. In some embodiments, chiplets 230 are mounted on interposer 210. Chiplets 230 may be mounted through physically manipulating each of chiplets 230 from back surfaces 234. Chiplets 230 may be mounted through pick and place assembly (e.g., on a temporary wafer with an adhesive laminate, on an adhesive laminate, etc.).

Material 260 may be disposed in gaps 250. Material 260 extends between side surfaces of chiplets 230 and side surfaces of interposer 210. Material 260 may bond the side surfaces of chiplets 230 to the side surfaces of interposer 210. In various such embodiments, the bond between chiplets 230 and interposer 210 is a covalent bond, mechanical bond, chemical bond, atomic bond, or any other appropriate bond. In some embodiments, material 260 is a molded material and the bond is a mechano-chemical bond.

In some embodiments, material 260 may be or include dielectric material, semiconductor material, metal(s), plastic(s), alloy(s), epoxy(s), biomaterial, or any other appropriate material(s). Material 260 may be an electrical insulator epoxy with electrical insulator particles. Material 260 may include silica or SiO₂ particles. Material 260 may be a conductive epoxy with conductive particles (e.g., metallic particles). In various embodiments, there is a dielectric layer or a space (e.g., air) between material 260 and one or more of interconnects 255 (only one of which is labeled), chiplets 230, encapsulation layer material 270, and interposer 210.

In some embodiments, gaps 250 have width gw of between one-fifth and ten times thickness tw of interposer 210 and/or chiplets 230. Gaps 250 may vary based on the shape, size, configuration, etc., of chiplets 230 and/or of cavities 220. In various embodiments, thickness tw is between 20 and 200 micrometers, is between 50 and 125 micrometers, may be nominally 75 micrometers, or is any other appropriate thickness. Though shown as uniform, thicknesses of one or more of chiplets 230 may vary from the thickness of interposer 210. In various embodiments, thickness te of encapsulation material layer 270 is between 3 and 100 micrometers, is between 5 and 25 micrometers, may be nominally 15 micrometers, or is any other appropriate thickness.

Encapsulation material layer 270 may be a high-thermal-conductivity backside metallization layer. In some embodiments, encapsulation material layer 270 improves heat transfer from chiplets 230 to interposer 210. Encapsulation material layer 270 may be a thermal plane that increases thermal conduction from chiplets 230 to encapsulation material layer 270 and/or interposer 210. Encapsulation material layer 270 may be in direct contact with chiplets 230 (e.g., to increase thermal conduction between chiplets 230 and encapsulation material layer 270). In various embodiments, encapsulation material layer 270 has a coefficient of thermal expansion between two of or equal to one of coefficients of thermal expansion of the interposer 210 and chiplets 230. In some embodiments, encapsulation material layer 270 is omitted. Chiplets 230 may be coupled to interposer 210 (e.g., via material 260).

Interconnects 255 electrically couple chiplets 230 to interposer 210. In the embodiment shown, interconnects 255 connect contacts 238 of chiplets 230 (only one of which is shown) to contacts 218 of interposer 210 (only one of which is labeled). Contacts 238 and contacts 218 are electrical (e.g., power, ground and/or signal) contacts on front surfaces 232 of chiplets 230 and front surface 212 of interposer 210, respectively. Interconnects 255 may be formed directly on or may be formed over (e.g., formed on a dielectric or air gap over) material 260. Interconnects 255 may include direct interconnect routing or traces extending from electrical contacts 238 to electrical contacts 218. Interconnects 255 may include low loss high-performance DC, RF, and mm-wave routing. In various embodiments, interconnects 255 are bonded to and/or directly attached to (e.g., in contact with) one or more of material 260, interposer 210, chiplets 230, contacts 238, and contacts 218. In some embodiments, interconnects 255 are wafer level interconnects. Electrical components or integrated circuits of interposer 210 may include components (e.g., metal routing) fabricated at the wafer scale. In various embodiments, interconnects 255 may be made using thin film conductors, plated interconnects, multilayer processes, or any other appropriate technique.

Interposer 210 includes one or more integrated ESD protection circuits (not shown). Electrical coupling between chiplets 230 and interposer 210 may be made via interconnects 255. This may improve performance, reliability, and yield for circuitry of chiplets 230. For example, chiplets 230 may be sensitive to ESD damage. One or more ESD protection circuits integrated within interposer 210 (e.g., before chiplets 230 are mounted on interposer 210) may protect chiplets 230 and circuits therein (e.g., HEMTs) from ESD damage after (e.g., as soon as) chiplets 230 are coupled to interposer 210 (e.g., electrically coupled via interconnects 255). The ESD protection circuits may provide ESD protection for chiplets 230 against ESD of or by at least one of a human or a human body model (HBM). The HBM may be used to test the susceptibility of device 200 to ESD. Thus, reliability and performance may be improved. Further, the yield for fabrication of devices utilizing chiplets 230 may be increased and cost (e.g., due to damage to chiplet 230) may be decreased.

In various embodiments, interposer 210 includes other electronic integrated circuits, contacts (e.g., contact pads), or other appropriate components. In some such embodiments, the components are formed on front surface 212. A passivation layer (not shown) may be arranged front surface 212. Conducting vias (e.g., TWVs) arranged through the passivation layer may connect components of interposer 210 (e.g., active or passive circuitry) to contacts 218 (e.g., contact pads) on front surface 212. Interposer 210 may be a silicon wafer or substrate, which may improve manufacturability on large wafer diameters.

Interposer 210 may include any integrated circuit, active or passive, made possible by a chosen manufacturing process (e.g., a CMOS manufacturing process). In some embodiments, interposer 210 includes one or more integrated circuit layers. The integrated circuit layers may be a fraction of thickness tw of interposer 210 (e.g., between 1/10 and 1/1000 of the thickness). In some embodiments, thickness tw of interposer 210 may be reduced after fabrication (e.g., before etching cavities 220, after application of material 260, etc.).

Chiplets 230 may include one or more transistors (e.g., HEMTs). The terminals of the transistors may be connected to at least one contact 238 (e.g., contact pad), such as by a conductive via (not shown). Chiplets 230 may include a substrate and/or one or more integrated circuit layers (e.g., formed on top of a substrate). The thickness of the integrated circuit layers may be a fraction of the thickness of the substrate and/or of chiplets 230 (e.g., between 1/10 and 1/1000 of the thickness of the substrate). In some embodiments, chiplets 230 are thinner than interposer 210. In such embodiments, material may be provided at the bottom of cavities 220 or cavities 220 may not extend through interposer 210 to account for this difference in thickness. Material 260 may contact the side surfaces of chiplets 230 along most of their height (e.g., at least 50% of their height, starting from near front surfaces 232 of chiplets 230). Material 260 may contact nearly all of the side surfaces of chiplet 230. In some embodiments, material 260 fills gap 250 (e.g., up to a level flush with front surface 212 of interposer 210). In some embodiments, material 260 and/or encapsulation layer material 270 hold chiplets 230 such that front surfaces 232 are flush with front surface 212 (e.g., are in the same plane, or have, with respect to each other, a small or negligible height difference).

Chiplets 230 may be bonded to interposer 210 while front surfaces 232 and front surface 212 are attached temporarily to an adhesive laminate (not shown). Front surfaces 232 and/or front surface 212 may be polished (e.g., chemical-mechanically polished). In some embodiments, front surfaces 232 and/or front surface 212 after removing the adhesive laminate to which they were temporarily attached.

In some embodiments, interposer 210 is configured to be diced along dicing lines (shown as dashed lines in FIGS. 2A-2C) including area 286 of interposer 210. Area 286 includes at least one chiplet of chiplets 230. A device (e.g., a chip) may be formed including area 286 and the included chiplet(s) of chiplets 230. Area 286 may also include at least one integrated ESD protection circuit. Area 286 may include other components (e.g., passive and/or active circuitry, contacts, etc.).

Electronic components in chiplets 230 and interposer 210 may be tested separately before assembling device 200. Thus, chiplets 230 may be tested to verify their functionality and/or performance before and/or after being mounted to interposer 210. Similarly, the components of interposer 210 may be tested prior to and/or after assembly to verify their functionality and performance. As a result, reliability and performance of device 200 may be improved. Further, the yield for fabrication of device 200 and/or devices formed by dicing device 200 may be increased. In some embodiments, the tested electronic components may be replaced to improve fabrication yield, functionality and/or performance of device 200. For example, in response to an electrical component of a chiplet type of chiplets 230 having fabrication yield below a threshold metric, the electrical component may be rejected and replaced with a different chiplet of chiplets 230. Other components of device 200 (e.g., interposer 210, other types of chiplets 230, etc.) may not require replacement. As such, the fabrication yields, functionality and performance of device 200 may be improved (without needing to recreate the entire assembly). Further, steps in the fabrication, integration, or testing of an electrical component that could potentially damage other components of device 200 may be performed without subjecting the other components to those steps. Thus, manufacturing costs of device 200 may be reduced, especially in embodiments where a portion of components of device 200 (e.g., a portion of chiplets 230) are more expensive, fragile, low-yield, etc., relative to another portion of components (e.g., interposer 210).

FIG. 2B is a schematic cross-sectional view of device 201 having heterogeneous integration of chiplets 230 (only one of which is labeled) into interposer 210. Interposer 210 includes one or more integrated ESD protection circuits.

As compared to device 200, device 201 does not include cavities 220, material 260, and encapsulation material layer 270. In the embodiment shown, chiplets 230 are mounted on front surface 212 of interposer 210. Interconnects 255 are on or above side surfaces of chiplets 230.

FIG. 2C is a schematic cross-sectional view of device 202 having heterogeneous integration of chiplets 230 (only one of which is labeled) into interposer 210. Interposer 210 includes one or more integrated ESD protection circuits.

As compared to device 200, cavities 220 of device 202 are shallower than interposer 210 (e.g., depressions in front surface 212). In the embodiment shown, chiplets 230 are mounted within cavities 220 of interposer 210 via material 260. In some embodiments, portions of chiplets 230 (e.g., back surface 234) may directly attach to (e.g., be in contact with) portions of interposer 210.

Devices 201 and 202 share many of the benefits of device 200. For example, the functionality and performance of components of chiplets 230 and interposer 210 may be separately tested and issues with performance accounted for. In addition, ESD protection circuits built in interposer 210 may be used to protect ESD sensitive chiplets 230 once chiplets 230 are integrated with interposer 210. Thus, manufacturing and performance of devices 201 and 202 may be improved.

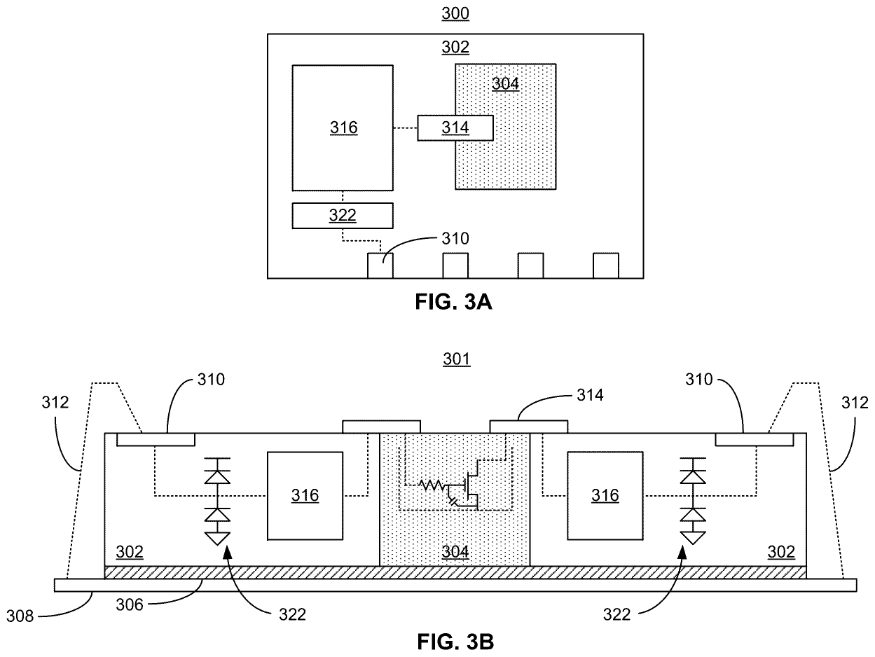

FIGS. 3A and 3B depict embodiments of devices 300 and 301 in which chiplets are integrated with interposers. FIG. 3A is a block diagram of device 300 having heterogeneous integration of chiplet 304 into interposer 302. FIG. 3B is a schematic cross-sectional view of electronic assembly 301 having heterogeneous integration of chiplet 304 into interposer 302. Interposer 302 includes integrated ESD protection circuit 322 and integrated circuitry 316. Chiplet 304 and integrated ESD protection circuit 322 may be one of multiple chiplets mounted onto interposer 302 and one of multiple ESD protection circuits integrated into interposer 302, respectively. In some embodiments, interposer 302 and chiplet 304 are analogous to interposer 210 and chiplets 230 of FIGS. 2A-2C. Although one chiplet 304 is shown for clarity, frequently another number of chiplets 304 (e.g., a larger number) may integrated with interpose 302.

In some embodiments, ESD protection circuit 322 includes one or more ESD diodes, i.e., reverse-biased diodes connected to the signal line (as shown in the embodiment of FIG. 3B). ESD protection circuit 322 may include a voltage supply rail to keep the ESD diodes reverse-biased relative to the voltage of the signal line. In some embodiments, ESD diodes are distributed along the signal line. In the embodiment shown, ESD diodes 322 are integrated into interposer 302 near wire bond pads 310 (only one of which is labeled in FIG. 3A). In various embodiments, integrated components of interposer 302 (including ESD protection circuit 322 and integrated circuitry 316) may be arranged in any appropriate configuration. For example, ESD protection circuit 322 and integrated circuitry 316 may be in separate portions and/or duplicated along the signal line. Integrated circuitry 316 may include at least one of a passive circuit and an active circuit. In various embodiments, integrated circuitry 316 includes resistors, capacitors (e.g., bypass capacitors), inductors, amplifiers, ESD circuits, diodes, through substrate vias, dielectric layers, signal traces, powered or ground traces, interconnects, wires, metal layers (e.g., signal traces, signal planes, etc.), contacts (e.g., wire bond pads), or any other appropriate circuit(s) or component(s).

Chiplet 304 may include one or more transistors (e.g., HEMTs such as InP HEMTs, in LNA(s)). The terminals of the transistors may be connected to at least one contact (e.g., contact pad) on chiplet 304 (e.g., by a conductive via). In various embodiments, chiplet 304 includes one or more resistors, capacitors, inductors, amplifiers, diodes, through substrate vias, dielectric layers, signal traces, powered or ground traces, interconnects, wires, metal layers (e.g., signal traces, signal planes, etc.), contacts (e.g., wire bond pads), or any other appropriate circuit(s) or component(s) (e.g., as shown in the embodiment of FIG. 3B). ESD protection circuits, such as ESD protection circuit 322, may provide ESD protection for chiplet 304 against ESD of or by at least one of a human or corresponding to the HBM. The HBM may be used to test the susceptibility of device 300 and/or electronic assembly 301 to ESD.

Interconnect 314 electrically couples chiplet 304 to interposer 302. In some embodiments, interconnect 314 is analogous to interconnects 255 of FIGS. 2A-2C. Interconnect 314 may be a wafer level interconnect. In the embodiment shown, interconnect 314 electrically couples chiplet 304 to integrated circuitry 316 in interposer 302. This may improve performance, reliability, and yield for circuitry of chiplet 304. For example, chiplet 304 may be sensitive to ESD damage. ESD protection circuit 322 is integrated into interposer 302 before chiplet 304 is mounted. ESD protection circuit 322 may thus protect chiplet 304 and circuits therein (e.g., HEMTs) from ESD damage as soon as chiplet 304 is coupled to interposer 302 (e.g., electrically coupled via interconnect 314). Thus, reliability and performance may be improved. Further, the yield for fabrication of device 300 and/or electronic assembly 301 may be increased.

Chiplet 304 may be mounted to interposer 302 through pick and place assembly (e.g., on a temporary wafer with an adhesive laminate, on an adhesive laminate, etc.). In some embodiments, chiplet 304 is mounted on interposer 302 though physically manipulating chiplet 304 from the back side. In some embodiments, chiplet 304 is mounted into a cavity of interposer 302 (e.g., as shown in the embodiment of FIG. 3B).

Electronic assembly 301 includes wire bonds 312 electrically coupling wire bond pads 310 to assembly substrate 308. In the embodiment shown, base layer 306 is coupled to assembly substrate 308 and to interposer 302. Base layer 306 may be directly attached to (e.g., in contact with) assembly substrate 308 and/or interposer 302. The bond between base layer 306 and assembly substrate 308 and/or interposer 302 may be a covalent bond, chemical bond, atomic bond, or any other appropriate bond. In some embodiments, base layer 306 is analogous to encapsulation material layer 270 of FIGS. 2A-2C.

Electronic assembly 301 includes multiple ESD protection circuits 322 integrated near wire bond pads 310. Wire bonds 312 may be formed after chiplet 304 is mounted to interposer 302. Thus, ESD protection circuits 322 may protect chiplet 304 and circuits therein (e.g., HEMTs) from ESD damage when electronic assembly 301 is formed.

Manufacturing, performance, and reliability of device 300 may be improved. Device 300 may be an electronic assembly or a portion of an electronic assembly (e.g., analogous to electronic assembly 301). In some embodiments, electronic assembly 301 includes device 300 (e.g., coupled to assembly substrate 308 via base layer 306). Electronic components in chiplet 304 and interposer 302 may be tested separately before assembling device 300 and/or electronic assembly 301. Thus, chiplet 304 may be tested to verify its functionality and/or performance before and/or after being mounted to interposer 302. Similarly, integrated components of interposer 302 may be tested prior to and/or after assembly to verify their functionality and performance. Moreover, the use of ESD protection circuits 322 may protect ESD sensitive chiplet 304 from damage or destruction during the assembly process. For example, chiplet 304 may be coupled with ESD protection circuits 322 prior to processes that are likely to induce ESD, such as wire bonding. As a result, reliability and performance of device 300 may be improved. Further, the yield for fabrication of device 300, electronic assembly 301, devices formed by dicing device 300 and/or electronic assembly 301, etc. may be increased. Protecting chiplet 304 from ESD damage during manufacturing may increase yield. This may be particularly beneficial for chiplets including expensive components, such as InP HEMTs. Improvements in yield due to a reduction in damage to such HEMTs may significantly reduce the cost of device 300 an/or assembly 301. In some embodiments, the tested electronic components may be replaced to improve fabrication yield, functionality and/or performance. For example, in response to an electrical component of chiplet 304 having fabrication yield below a threshold metric, the electrical component may be rejected and replaced with a different chiplet. Other components of device 300 and/or electronic assembly 301 (e.g., interposer 302, other chiplets, etc.) may not require replacement. As such, the fabrication yields, functionality and performance of device 300 and/or electronic assembly 301 may be improved (without needing to recreate the entire device or electronic assembly). Further, steps in the fabrication, integration or testing of an electrical component that could potentially damage other components may be performed without subjecting the other components to those steps. Thus, manufacturing costs of device 300 and/or electronic assembly 301 may be reduced, especially in embodiments where a portion of components (e.g., chiplet 304) are more expensive, fragile, low-yield, etc., relative to another portion of components (e.g., interposer 302).

For example, applications such as quantum computers, satellite communications, or even data centers may use a large number of LNAs, a large number of HEMTs, and, therefore, a large number of chiplets 304. The cost of HEMTs, such as InP HEMTs usable at very low temperatures, and LNAs including such HEMTs may be thousands of dollars. Reduction in the cost of devices 300 and 301 and improvements in yield for devices 300 and 301 may greatly reduce the cost of quantum computers, satellite communications and/or data centers. Thus, devices 300 and 301 may greatly facilitate quantum computing, satellite communications, and/or electronics for data centers.

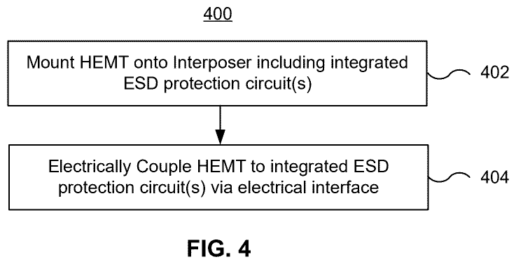

FIG. 4 is a flow diagram illustrating an embodiment of process 400 for heterogeneous integration with ESD protection. In 402, a HEMT is mounted onto an interposer. The interposer includes one or more ESD protection circuits. In the embodiment shown, the interposer includes at least one semiconductor material and an electrical interface. In 404, the HEMT is electrically coupled to the integrated ESD protection circuit(s) through the electrical interface. Both 402 and 404 may be carried out using techniques, such as pick and place and the use of wafer level interconnects, that are unlikely to damage the HEMT. For example, the HEMT may be integrated in a chiplet including a front side and a back side. Mounting the HEMT in 402 includes physically manipulating the chiplet including the HEMT from the back side. In some embodiments, the HEMT being mounted on the interposer includes electrically coupling the HEMT to the ESD protection circuit through at least one wafer level interconnect in the interposer. Thus, ESD sensitive chiplets may be more readily integrated into a device. Consequently, reliability, performance, and yield may be increased while reducing cost.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A device, comprising:
an interposer including at least one semiconductor material;
a high electron mobility transistor (HEMT) mounted on the interposer; and
an electrical interface between the HEMT and the interposer;
wherein the interposer includes an integrated electrostatic discharge (ESD) protection circuit that is coupled to the HEMT through the electrical interface of the interposer.

2. The device of claim 1, wherein the integrated ESD protection circuit is provided in the interposer before the HEMT is mounted on the interposer.

3. The device of claim 1, wherein the HEMT is included in a low noise amplifier (LNA).

4. The device of claim 3, wherein the LNA is configured for operation at temperatures as low as 3 Kelvin and wherein the HEMT is an InP HEMT.

5. The device of claim 1, wherein the HEMT is integrated in a chiplet including a front side and a back side, and wherein the HEMT is mounted on the interposer though physically manipulating the chiplet from the back side.

6. The device of claim 1, wherein the HEMT is electrically coupled to the integrated ESD protection circuit through at least one wafer level interconnect.

7. The device of claim 1, wherein the integrated ESD protection circuit includes a plurality of diodes integrated into the interposer.

8. The device of claim 1, wherein the integrated ESD protection circuit provides ESD protection for the HEMT against ESD of or by at least one of a human or a human body model (HBM).

9. The device of claim 1, wherein the interposer includes a wafer having a cavity therein, the HEMT being mounted in the cavity, the wafer including at least one of a passive circuit and an active circuit in addition to the integrated ESD protection circuit.

10. An electronic assembly, comprising:
an interposer having a plurality of electro-static discharge (ESD) protection circuits integrated therein; and
a plurality of ESD sensitive chiplets being coupled with the interposer and electrically coupled with the integrated ESD protection circuits through the interposer.

11. The electronic assembly of claim 10, wherein the plurality of ESD protection circuits is provided in the interposer before the plurality of ESD sensitive chiplets is mounted on the interposer.

12. The electronic assembly of claim 10, wherein the plurality of ESD sensitive chiplets includes a plurality of high electron mobility transistors (HEMTs).

13. The electronic assembly of claim 12, wherein the plurality of HEMTs is included in a plurality of low noise amplifiers (LNAs) in the plurality of ESD sensitive chiplets.

14. The electronic assembly of claim 10, wherein a chiplet of the plurality of ESD sensitive chiplets includes a front side and a back side, and wherein the chiplet is mounted on the interposer though physically manipulating the chiplet from the back side.

15. The electronic assembly of claim 14, wherein the chiplet includes a high electron mobility transistor (HEMT); and
wherein the plurality of ESD sensitive chiplets being coupled to the interposer includes mounting the plurality of ESD sensitive chiplets on the interposer and electrically coupling the HEMT to at least one ESD protection circuit of the plurality of ESD protection circuits through at least one wafer level interconnect in the interposer.

16. The electronic assembly of claim 15, wherein the at least one ESD protection circuit provides ESD protection for the HEMT against ESD of or by at least one of a human or a human body model (HBM).

17. The electronic assembly of claim 10, wherein the interposer includes a wafer having a cavity therein, a chiplet of the plurality of ESD sensitive chiplets being mounted in the cavity, the wafer also including at least one of a passive circuit and an active circuit in addition to the integrated ESD protection circuit.

18. A method, comprising:
mounting, in an interposer including at least one semiconductor material, a high electron mobility transistor (HEMT), the interposer including an integrated electrostatic discharge (ESD) protection circuit and an electrical interface; and
electrically coupling the HEMT to the integrated ESD protection circuit through the electrical interface.

19. The method of claim 18, wherein the integrated ESD protection circuit is provided in the interposer before the HEMT is mounted on the interposer.

20. The method of claim 18, wherein the HEMT is integrated in a chiplet including a front side and a back side, and wherein the mounting the HEMT includes:
mounting the HEMT on the interposer though physically manipulating the chiplet from the back side.

21. The method of claim 18, wherein the mounting the HEMT on the interposer includes electrically coupling the HEMT to the integrated ESD protection circuit through at least one wafer level interconnect in the interposer.
